(19) United States
(12) Patent Application Publication
(10) Pub. No.: US 2015/0027509 A1
(43) Pub. Date: Jan. 29, 2015

(54) SUPPORTING STRUCTURE FOR PHOTOVOLTAIC PANEL

(71) Applicant: Alexander Levin, Binyamina (IL)

(72) Inventor: Alexander Levin, Binyamina (IL)

(21) Appl. No.: 13/950,285

(22) Filed: Jul. 25, 2013

(51) Int. Cl. H01L 31/052; H01L 31/042

(52) U.S. Cl. CPC H01L 31/0521; H01L 31/0424
USPC 136/246

(57) ABSTRACT

The invention relates to a field of photovoltaic panels, and specifically to photovoltaic panels operating with irrigation of their backsides by liquid heat transfer medium.

More specifically, the invention proposes a supporting structure for active cooling a photovoltaic solar panel fastened on a supporting metal plate, which is irrigated on its backside with relatively low flow rate of heat transfer medium, which flows in the form of some rivulets. The invention describes some technical solutions, which restrict meandering rivulets flow on this backside.

The proposed supporting structure in combination with an installed photovoltaic panel can be used at nighttime for cooling water or another heat transfer medium. This cooled water can be applied for air conditioning of a dwelling or for cooling the photovoltaic panels at daylight time.

### STATEMENT REGARDING FEDERALLY SPONSORED RESEARCH

Not applicable.

### FIELD OF THE INVENTION

The invention relates to a field of photovoltaic solar panels and specifically to photovoltaic solar panels cooled by a liquid medium.

### BACKGROUND OF THE INVENTION

It is known, that the output of a solar cell (and, therefore, of a photovoltaic panel) is affected by its temperature. As a result the power output will be reduced by between 0.25% (amorphous cells) and 0.5% (most crystalline cells) for each degree C. of temperature rise. Panel's temperatures in the summer in warm climates can easily reach 50° C. resulting in a 12% reduction in output compared to the rated output at 25° C.

In such a way, it is desirable to design photovoltaic solar panels provided with their active cooling by water or another cooling medium.

Such photovoltaic panels are described in several patents and patent applications.

U.S. Pat. No. 3,976,508 describes tubular solar cells which can be coupled together in series and parallel arrays to form an integrated structure. Solar energy concentrators are combined with the solar cells to maximize their power output. The solar cells may be cooled by circulating a heat exchange fluid through the interior of the solar cells and the heat captured by such fluid may be utilized, for example, to provide hot water for a heating system. The coolant circulating system of the solar cells also may be integrated with a solar thermal device so as to form a two-stage heating system, whereby the coolant is preheated as it cools the solar cells and then is heated further by the solar thermal device.

U.S. Pat. No. 4,056,405 describes a panel for mounting solar energy cells, and particularly those cells upon which light is to be concentrated, includes an enclosure for holding the cells and has at least one wall formed from a good conductor of heat. The cells are mounted within the enclosure on a resinous cushion that is a relatively good conductor of heat and a poor conductor of electricity, so that when heat is generated by impingement of light on the cells, it will be carried by the cushion to the enclosure wall and dissipated therefrom.

U.S. Pat. No. 4,080,221 describes a system for converting solar energy into electric energy at reduced cost. This system makes use of an array of light sensitive, voltage producing solar cells of the flat disc silicon type. To increase power, while using fewer costly cells, each cell of the array has a truncated conical shell mounted on legs at a spaced distance thereover, the shell having a mirror-like reflective inner surface. Thus, sunlight is received in the large end and reflected through the small end to the cell. A sealed weather-tight enclosure for the array has fluid inlets and outlets for producing heat, the heat conductive shells absorbing and radiating heat.

U.S. Pat. No. 4,149,903 describes a hybrid solar energy collecting device adapted to generate an electrical current from sunlight and also to collect in an electrically insulating fluid thermal energy generated by such cells. The solar energy collecting device comprises a duct adapted for guiding the flow of an electrically insulating fluid such as air, and one or more photovoltaic cells mounted on an electrically insulated portion of the exterior surface of the duct. At least one of the photovoltaic cells has a heat sink which extends into the interior of the duct and is adapted to be contacted by the electrically insulating fluid.

U.S. Pat. No. 4,211,581 describes a solar photoelectric conversion apparatus comprising a light converter immersed in a transparent liquid heat carrier which occupies the lower part of the cavity of a hollow hermetically sealed reservoir. The apparatus also includes a solar radiation concentrator inserted in a beam of a solar radiation incident on an active surface of the light converter. During operation of the apparatus, vapors of the heat carrier condense on the inner walls of the reservoir and return by gravity to the liquid in the lower portion of the cavity, thereby cooling the liquid and the light converter immersed therein by “thermal siphon” action.

U.S. Pat. No. 4,278,829 describes an apparatus for converting solar energy to more useful forms, i.e., thermal and electrical energy. Such apparatus includes a photoelectric transducer (e.g., an array of photovoltaic cells), means for concentrating solar energy on the transducer, and means for circulating a liquid between the transducer and the solar energy concentrator. The spectral properties of the liquid are such that the liquid functions as a bandpass filter, transmitting solar energy to which the transducer is responsive and absorbing solar energy to which the transducer is non-responsive. The transmitted solar energy is converted to electrical energy by the transducer, and the absorbed solar energy is converted to heat by the liquid. Preferably, the liquid is circulated through a container which, in the vicinity of the transducer, is constructed so as to provide optical gain to the system and to integrate incident solar energy for the purpose of eliminating “hot spots” which could overheat, and thereby damage, the transducer.

U.S. Pat. No. 4,392,007 describes a support for at least one photovoltaic cell, comprising at least one block made of heat-conducting material with which said cell is in close thermal contact. According to the invention, this support comprises at least one tube the wall of which may be traversed by the heat, said tube being fastened to said block, in thermal contact therewith, and closed at its end to define a closed cavity inside which an evaporable and condensable fluid is enclosed. The invention is particularly applicable to a solar generator.

U.S. Pat. No. 4,587,376 describes an apparatus in which amorphous silicon solar cells are formed on a heat collecting plate. The solar cells are formed by using a superstrate or a substrate. Both a light-permeable superstrate and a metallic substrate are available for use. If the light-permeable superstrate is adopted, metallic electrodes, formed on the side of the heat collecting plate as lower electrodes of the solar cells, are attached to the heat collecting plate through electrically insulating adhesives, provided that the upper surface of the superstrate is exposed against the incident sunlight. The light-permeable superstrate is made of a heat absorbing material transmitting light having a wavelength range which is absorbed by the amorphous silicon layer of the solar cells while absorbing light having a wavelength range which is transmitted through the amorphous silicon layer thereby to convert the light into thermal energy. [0015] Alternatively, a heat absorbing layer made of a material having the above-mentioned property may be provided on a transparent superstrate. On the other hand, if the metallic substrate is used, the substrate is also available for the heat collecting plate, or is attached to the heat collecting plate while said heat absorbing layer may be provided on transparent electrodes formed on the upper side of the substrate as upper electrodes of the solar cells.

U.S. Pat. No. 6,005,184 describes a solar panel having a lightweight honeycomb core as a support for an upper surface array of solar cells. The upper surface of the core is bonded to an upper insulation/faceskin laminate, and the lower surface of the core is bonded to a heat dissipation/faceskin laminate having an undersurface for absorbing heat from the solar cells and dissipating the heat into space for cooler operation and increased power efficiency of the solar panel. The invention resides in the use of a heat dissipation layer of curable resin and carbon powder having increased heat-emission properties.

U.S. Pat. No. 7,728,219 describes a photovoltaic cell, which has electrodes, p- and n-junctions, and a heat sink. The heat sink is on a side of the cell opposite to the light-receiving side of the photovoltaic cell. The photovoltaic cell may also have heat-conducting channels within an interior of the photovoltaic cell that conduct heat from the interior of the photovoltaic cell to the heat sink. The heat sink can remove heat caused by light absorbed by the photovoltaic cell but not converted to electricity as well as heat generated by resistance to high current passing through electrodes of the photovoltaic cell. A module formed of such cells can exhibit greater energy conversion efficiency as a result of the ability to dissipate the heat. A method of making a solar cell or module involves e.g. laminating a heat sink to a photovoltaic cell as described above.

US Patent Application No. 20060137733 describes a photovoltaic module; this photovoltaic module comprises: a photovoltaic material; and a heat sink in thermal communication with the photovoltaic material proximate a mounting surface of the heat sink, the heat sink comprising a plurality of fins that are movable between a first position substantially parallel to the mounting surface of the heat sink and a second position substantially non-parallel to the mounting surface of the heat sink.

US Patent Application No. 20080006320 describes a cooling device for a photovoltaic panel, where the cooling device comprises a basis layer with a number of protruding structures which protrudes from the basis layer and where the cooling device covers a substantial part of the back of the photovoltaic panel.

US Patent Application No. 20080135094 describes a photovoltaic the with photovoltaic cell and a heat sink. The heat sink is attached on a side of the cell opposite to the light-receiving side of the photovoltaic cell and can remove heat caused by light absorbed by the photovoltaic cell but not converted to electricity as well as heat generated by electrical resistance. A photovoltaic tile formed of such cells can exhibit greater energy conversion efficiency as a result of the ability to dissipate the heat. The tiles can be arranged on a roof to protect the roof structure and generate electricity. Photovoltaic tiles comprising interlocking mechanical and electrical connections for ease of installation are described. Methods of making photovoltaic tiles involve e.g. laminating a heat sink to a photovoltaic cell and/or injection molding.

These patents and patent applications have a common drawback: they do not provide effective method of cooling the photovoltaic panels with high efficiency; i.e. with sufficiently high heat transfer coefficient between a cooling liquid medium and the backsides of the photovoltaic panels.

### BRIEF SUMMARY OF THE INVENTION

This invention proposes a design of a supporting structure for a photovoltaic panel, which is characterized by rivulets' flow on the backside of a supporting metal plate serving for installation of the photovoltaic panel.

The invention presents realization of several technical solutions disclosed by the author of this invention in U.S. patent application Ser. No. 13/714,697 filed on Dec. 14, 2012, which describes a flat-plate solar collector for water heating.

It is desirable to provide again some scientific results, which are substantiating the proposed designs of the aforementioned supporting structure for a photovoltaic panel with active cooling.

Effective cooling of a common photovoltaic panel with the length of the order 1600 mm requires specific rate of cooling water about 50 l/h or less on one meter of its width.

It is known that such specific rate cannot ensure flow of cooling water on a tilted surface in the form of a liquid film.

In another words, application of open-flow of cooling water for cooling the back sheet of the photovoltaic panel (through a supporting metal plate) leads to formation of some rivulets flowing on this supporting metal plate.

It is known too that for low magnitudes of liquid flow rate on an inclined or vertical plate the liquid flow pattern is characterized by a system of narrow rivulets with relatively small width (for water and aqueous solutions—in the region of 1-8 millimeter).

Detailed theoretic analysis of rivulets' flow and their stability is presented in the article: E. S. Benilov, “On the stability of shallow rivulets”, J. Fluid Mech. (2009), vol. 636, pp. 455-474. Pp. 461-462 of this article gives demonstration of stability of a rivulet flowing on the underside (backside) of an inclined plate.

The article: A. Daerr et a “General Mechanism for the Meandering Instability of Rivulets of Newtonian Fluids”, PHYSICAL REVIEW LETTER, SPRL 106, 184501 (2011) demonstrates that a rivulet flowing down an inclined plane often does not follow a straight path, but starts to meander spontaneously. This instability is the result of two key ingredients: fluid inertia and anisotropy of the friction between the rivulet and a substrate. Meandering only occurs if the motion normal to the instantaneous flow direction is more difficult than parallel to it. Above the threshold, the rivulet follows an irregular pattern with a typical wavelength of a few centimeters.

The article: Nolwenn LE GRAND-PITEIRA et al. “What governs rivulet meanders on an inclined plane?” (Oct. 11, 2005, CCSD—00011140, Internet) shows that a rivulet flow is highly hysteretic: the shape of the meanders varies with flow rate only for increasing flow rates, and the straight rivulet regime does not appear for decreasing flow rate.

Also a main object of this invention is to provide simple means limiting the meandering phenomena of rivulets flowing on the backside of a supporting metal plate serving for installation of a photovoltaic panel.

A supporting structure with an active cooling proposed in this invention is designed from following main units:
a supporting structural frame which comprises a top rectangular frame and a bottom rectangular frame joined by some connectors; the top rectangular frame serves for installation of a supporting metal plate; the photovoltaic panel with its back sheet to be mounted on the supporting metal plate by adhesive and this supporting structural frame is positioned in its operating state in such a way, that the top rectangular frame is tilted with respect to the horizontal plane;
a receiving chute, which is joined with the lower section of the backside of the supporting metal plate; this receiving chute is provided with an outlet connection serving for removal of cooling liguid medium;
a distributing pipe; the proximal section of this distributing pipe is placed outside the supporting metal plate, and its middle and distal sections are installed on the backside of the supporting metal plate; the middle and distal sections of this distributing pipe are provided with openings or nozzles, which supply evenly water or another cooling liquid medium on the upper section of the backside of the supporting metal plate; the upper section of the backside of the supporting metal plate is provided with some pipe clips serving for fastening the distributing pipe;
longitudinal members for restricting rivulets' flow meandering, which divide the backside of the supporting metal plate into a set of parallel zones; these longitudinal members for restricting rivulets' flow meandering entrap the rivulets when they meet the longitudinal members for restricting rivulets' flow meandering with following transformation of the shapes of these rivulets and flowing the rivulets in their transformed shapes along the longitudinal members.

In most versions of this invention the supporting metal plate is fabricated from ferromagnetic steel and appear as “a supporting steel plate”.

In another version of this invention the supporting structural frame serves as a skeleton for construction of a housing, which comprises a bottom wall, lateral walls, a proximal face wall and a distal face wall.

The lateral walls are provided with one opening (in one of their upper sections) for insertion of the distributing pipe and with an outlet connection (in one of their lower sections) for drainage of the cooling liquid medium.

In addition, one lateral wall is provided with a venting hole.

A receiving chute is not applied in this version because the lower section of the housing plays a role of a collector for the cooling liquid medium before its drainage.

The can be designed on the base of several physical principles.

These longitudinal members for restricting rivulets' flow meandering may operate on the base of capillary forces, gravitational force or by application of body force tangent to the substrate surface in opposite direction as a driving shear surface (see, for example, S. Marshall and S. Wang CONTACT LINE FINGERING AND RIVULET FORMATION IN THE PRESENCE OF SURFACE CONTAMINATION, Computers&Fluids, V.34, Issue 6 July 2006, pp. 664-683).

It should be noted that for very low values of flow rate, a drop-wise flow can precede formation of rivulets' flow. This invention proposes in this case the same longitudinal members for restricting rivulets' flow meandering.

In a first version of design of longitudinal members for restricting rivulets' flow meandering, they are fabricated as strips from fridge magnets (polymer bond magnets), which are arranged on the backside of a supporting steel plate; this supporting steel plate has required ferromagnetic properties ensuring tight adjacency of the fridge magnet strips to the backside of the supporting steel plate.

The fridge magnet strips are fabricated preferably on the base of thermo-stable polymer.

The backside of the supporting steel plate is covered preferably with corrosion resisting thermo-stable paint or coating.

Rivulets (or drops) are formed by supplying water (or aqueous solution), which is provided via the openings of the distributing pipe on the upper section of the backside of the supporting steel plate.

The rivulets flow downwards along this backside of the supporting steel plate and in the case of their meandering and contacting with the edges of the fridge magnet strips they continue to flow along these edges as a result of the capillary force.

The second version of the invention proposes application of relatively short fridge magnet strips, which are arranged on the backside of the supporting steel plate as vertical rows of the cascade-wise fridge magnet strips, wherein each fridge magnet strip in one row of the vertical cascade-wise system has a certain angle with the longitudinal direction (main direction of free rivulets flow) of the supporting steel plate; this angle is chosen in such a way, that it ensures flowing each rivulet along the edge of the fridge magnet strip from a place of their initial contact. It allows to increase the total surface of the rivulets flowing on the backside of the supporting steel plate.

In the third version of the invention a supporting steel plate has required ferromagnetic properties and its backside is covered with corrosive resisting paint or coating.

Parallel steel strips with analogical ferromagnetic properties are covered on their both sides and their edges with corrosive resisting paint or coating, and they are placed apart longitudinally with a certain mutual interval on the backside of the supporting steel plate; each steel strip is fastened on the backside of the supporting metal plate by some permanent magnets.

The preferable thickness of these steel strips lies in the range of 0.1-1.2 mm.

The steel strip may be provided with at least one longitudinal bead, which forms a wedge-wise gap with the adjacent surface of the backside of the supporting steel plate; this wedge-wise gap confines flow of the rivulet by capillary forces.

In such a way, such wedge-wise gap transforms the rivulet pattern flow to flow of a thin liquid layer; this thin liquid layer if confined by the internal surfaces of the wedge-wise gap and a meniscus formed on the free surface of the thin liquid layer.

In the fourth version of this invention the aforementioned strips may be fabricated from any corrosion-resisting material (steel with anticorrosive coating, copper, thermo-stable polymer etc.).

Each strip in this version is provided with one or two longitudinal beads and some openings, wherein each opening is provided with a vertical flanging; there is an O-ring (or a back-up ring) to be inserted into each opening; a truncated conical permanent magnet keeps dose this O-ring (or back-up ring) against the opening flanging; the truncated conical permanent magnet is inserted into the opening until Its immediate contact with the backside of the supporting steel plate with attendant deformation of the O-ring (or the back-up ring).

In a simpler version of this technical solution, the strips are provided with some openings and O-rings (or back-up rings), which are placed concentrically with these openings; the diameter of each opening lies in the interval between the inner diameter of the O-ring and its outer diameter.

A truncated conical permanent magnet, which has its top diameter smaller that the inner diameter of the O-ring and its base diameter is larger that the inner diameter of the O-ring, is to be inserted with its truncated section into the opening until its immediate contact with the backside of the supporting steel plate. The top and base diameters of the O-ring are chosen in such a way, that this insertion causes radial extension of O-ring, and friction forces between the truncated conical permanent magnet and this O-ring held in place the strip in contact with the backside of the supporting steel plate.

It should be noted that cylindrical permanent magnets can be used instead of the conical truncated permanent magnets. In this case the diameter of the cylindrical permanent magnet is larger than the inner diameter of the O-ring.

In the fifth version of the invention the longitudinal strips, which are provided with two longitudinal beads (two lateral strips are provided with one bead each one), are constructed as a grate with a frame comprising two lateral strips with one bead each one and upper and lower webs joining the beads of the neighboring strips.

The gap between the webs and the backside of the supporting metal plate is chosen in such a way, that it allows free entrance of the rivulets flowing on the backside of the supporting steel plate to the areas between the neighboring longitudinal strips. The grate may be fastened on the backside of the supporting steel plate by the same means as in the case of the strips, i.e., combinations of openings with permanent magnets and O-rings which have been described previously.

It should be noted that the auxiliary grate (or strips) itself does not present a capillary taking up structure.

However, combination of the supporting steel plate with the fastened auxiliary grate provides wetting of a significant part of the backside of the supporting steel plate by the supplied cooling liquid medium owing capillary effect caused by the narrow gap between the auxiliary grate (or strips) and the backside of the supporting metal plate.

If instead of steel the supporting plate is fabricated from a corrosion-resisting metal (for example—copper), than the proposed structures of the backside of the supporting metal plate with the longitudinal strips (or the auxiliary grate comprising the longitudinal strips) may be realized without application of the fridge magnet strips or permanent magnets.

In such designs, which are analogical to the first, second and third versions of the invention, fridge magnet strips are substituted by longitudinal strips from any corrosion resisting material and; these longitudinal strips are joined with the backside of the supporting metal plate by seam or spot welding, soldering or gluing with thermo-stable glue.

In a following version of the invention, the backside of an supporting metal plate is covered with a thermo-stable hydrophobic coating; parallel longitudinal lands of the surface of the hydrophobic coating are treated by known methods (plasma treating, chemical oxidation etc.) providing hydrophilic properties to these parallel longitudinal lands.

In such a way, this technical solution creates longitudinal boundaries of the parallel longitudinal lands on the surface of the aforementioned thermo-stable coating having high value of hysteresis of the surface tension.

In addition, the parallel hydrophilic lands may be obtained by spray coating with metal or dielectric powder having hydrophilic property.

It is known [see the article: E. S. Benilov On the stability of shallow rivulets, J. Fluid Mech. (2009), vol. 636, pp. 455-474] that high values of surface tension hysteresis stabilize rivulets' flow and prevent their unlimited meandering.

In such a way, these hydrophilic longitudinal ands present attraction areas for rivulets and cause their capturing.

A photovoltaic panel with the proposed supporting structure should be installed with a certain angle of inclination to the horizontal plane.

In addition, the upper and lower edges of the supporting metal plate (or supporting steel plate) serving for installation of the photovoltaic panel may have a distinct angle of inclination with respect to the horizontal plane; this provides possibility that most of rivulets will contact with the longitudinal members for restricting rivulets' meandering from a same side.

The distributing pipe may be designed thus to provide immediate contact of a supplied cooling liquid medium (water or another liquid medium) with the upper section of the backside of the supporting metal plate (or supporting steel plate).

The supporting structure for active cooling a photovoltaic solar panel as claimed in claim 1, wherein

A photovoltaic panel in combination with the proposed supporting structure can be used at nighttime for cooling water or another liquid medium. This cooled water can be applied for air conditioning of a dwelling or for its storing with following cooling the photovoltaic panels at daylight time.

### BRIEF DESCRIPTION OF THE SEVERAL VIEWS OF THE DRAWINGS

FIG. 1a demonstrates an isometric view of a supporting structural frame with an installed receiving chute.

FIG. 1b demonstrates an isometric view of a housing, which includes the supporting structural frame serving as a skeleton of this housing.

FIG. 2a demonstrates a vertical cross-section of a photovoltaic panel with a supporting structural frame and a supporting metal plate.

FIG. 2b demonstrates a vertical cross-section of the photovoltaic panel with the supporting structural frame and a housing.

FIG. 3a is an underside view of a supporting steel plate with a bank of longitudinal fridge magnets strips and a distributing pipe fastened on the supporting steel plate.

FIG. 3b is an underside view of the supporting steel plate with a zigzag arrangement of fridge magnet strips and the distributing pipe fastened on the supporting steel plate.

FIG. 3c is the underside view of a supporting metal plate with a hydrophobic coating, longitudinal hydrophilic lands on this hydrophobic coating and a distributing pipe fastened on the supporting metal plate.

FIG. 4a, FIG. 4b and FIG. 4c are the top view and transverse cross-sections A-A and B-B of a grate-wise bank of strips with beads.

FIG. 5a, FIG. 5b and FIG. 5c are a top view and transverse cross-sections A-A and B-B of a grate-wise bank of strips with beads, wherein these strips are provided with openings.

FIG. 6a and FIG. 6b are cutaway transverse views of the supporting steel plate with installation of a strip (FIG. 6a) or a grate-wise bank of strips (FIG. 6b) by permanent magnets, wherein the strip or of the grate-wise bank of strips are provided with openings.

FIG. 7a and FIG. 7b are cutaway transverse views of the supporting steel plate with installation of a strip (FIG. 7a) or a grate-wise bank of strips (FIG. 7b) by permanent magnets, wherein the strip (or the grate-wise bank of strips) is provided with flanged openings.

FIG. 8a and FIG. 8b are cutaway transverse views of the supporting steel plate serving for installation of a photovoltaic panel with fastening a strip with one bead (FIG. 8a) or a strip with two beads (FIG. 8b) by external permanent magnets.

FIG. 9 is a cutaway transverse view of the upper section of a supporting metal plate serving for installation of a photovoltaic panel with an installed distributing pipe.

### DESCRIPTION OF PREFERRED EMBODIMENTS

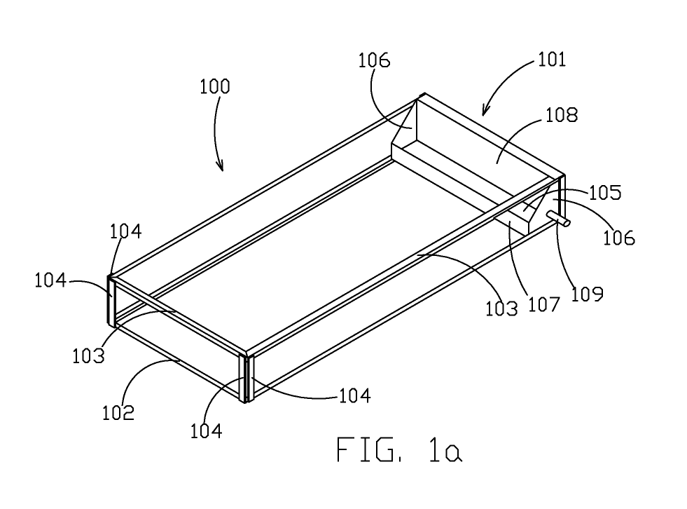

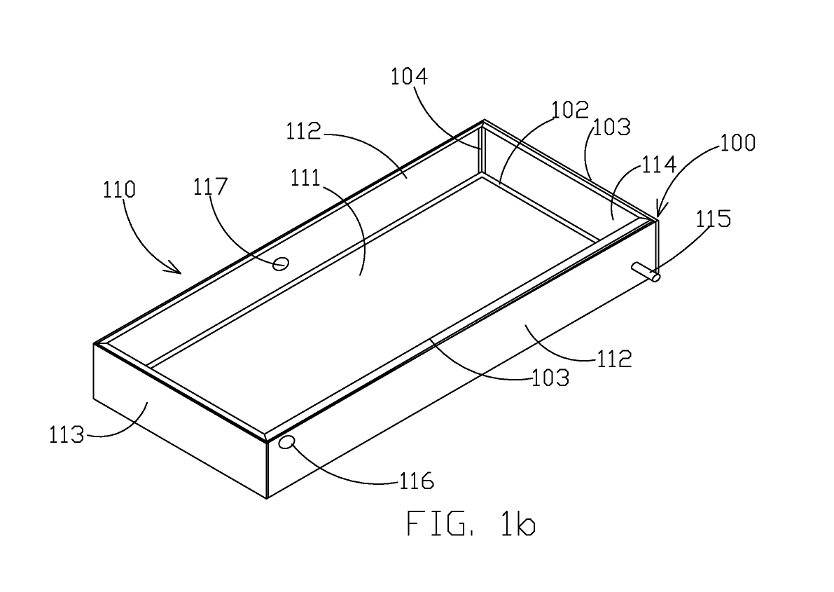

FIG. 1a demonstrates an isometric view of a supporting structural frame 100 with an installed receiving chute 101.

The supporting structural frame 100 comprises: a bottom frame 102; an upper frame 103; connectors 104.

The receiving chute 101 comprises: a bottom wall 105; lateral walls 106; forward and rear walls 107 and 108; an outlet connection 109.

FIG. 1b demonstrates an isometric view of the supporting structural frame 100 with housing 110 formed by bottom, lateral, forward and rear walls.

The supporting structural frame 100 comprises: the bottom frame 102; the upper frame 103; connectors 104.

Housing 110 comprises: a bottom wall 111; lateral walls 112; forward and rear walls 113 and 114; an outlet connection 115 maintained on one lateral wall 112.

One lateral wall 112 is provided with opening 116, which serves for inserting a distributing pipe, and with a venting hole 117.

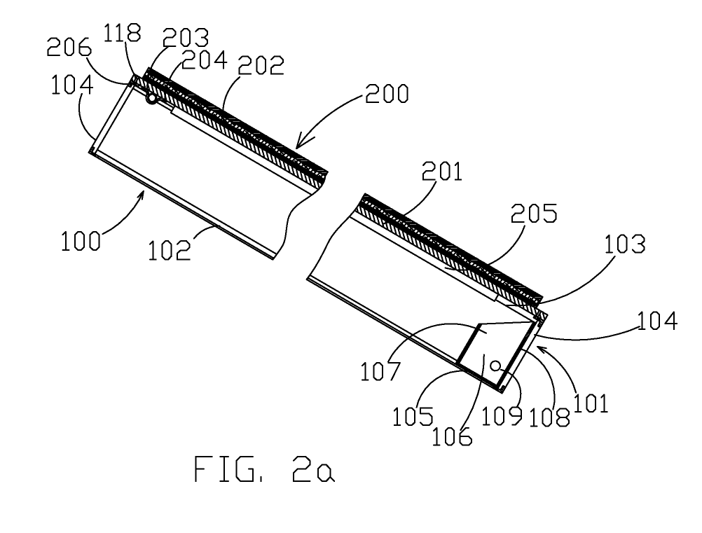

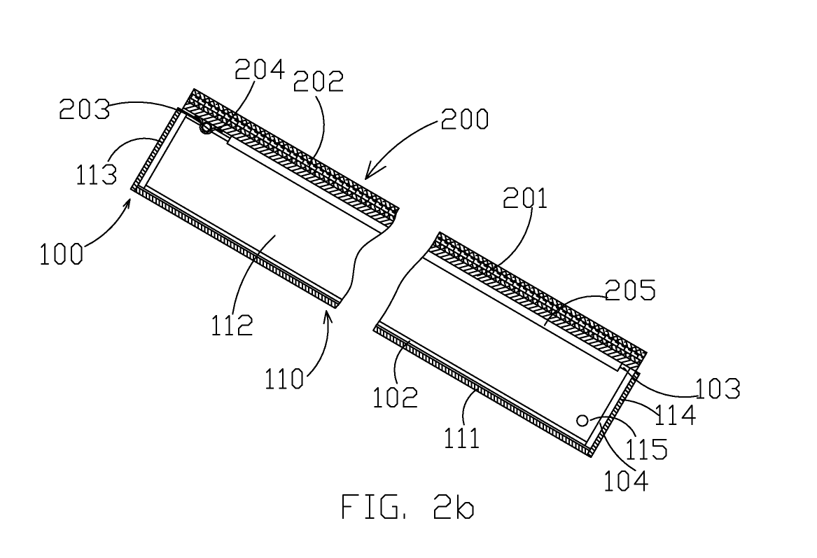

FIG. 2a demonstrates a vertical cross-section of a photovoltaic panel 200 with the supporting structural frame 100, a receiving chute 101 and the supporting metal plate 201.

It comprises the supporting metal plate 201 serving for installation of a photovoltaic panel 200.

The photovoltaic panel 200 is provided with a front transparent cover 202 and a back dielectric cover 206.

The supporting structural frame 100 comprises: the bottom frame 102; the upper frame 103; connectors 104.

The receiving chute 101 comprises: a bottom wall 105; lateral walls 106; forward and rear walls 107 and 108; an outlet connection 109.

A distributing pipe 203 is installed on the upper section of the backside of the supporting metal plate 201; the proximal section of the distributing pipe 203 is placed outside the supporting metal plate 201 and its middle and distal sections are situated underneath of the backside of the supporting metal plate 201; the distributing pipe 203 is installed on the backside of the supporting metal plate 201 by pipe clips 204.

Longitudinal members 205 for restricting rivulets* flow meandering divide the backside of the supporting metal plate 201 into a set of parallel zones; these longitudinal members 205 for restricting rivulets flow meandering entrap the rivulets when they meet the longitudinal members 205 with following flow of the rivulets along the longitudinal members 205.

FIG. 2b demonstrates a vertical cross-section of the photovoltaic panel 200 with the supporting structural frame 100, housing 110 and a supporting metal plate 201.

It comprises: the supporting metal plate 201 serving for installation of a photovoltaic panel 200.

The photovoltaic panel 200 is provided with the front transparent cover 202 and the back dielectric cover 206.

The supporting structural frame 100 comprises: the bottom frame 102; the upper frame 103; connectors 104.

Housing 110 comprises: a bottom wall 111; lateral walls 112; forward and rear walls 113 and 114; an outlet connection 115 maintained on one lateral wall 112.

One lateral wall 112 is provided with opening 116, which serves for inserting a distributing pipe, and with a venting hole 117.

The distributing pipe 203 is installed on the upper section of the backside of the supporting metal plate 201; the proximal section of the distributing pipe 203 is placed outside the supporting metal plate 201 and its middle and distal sections are situated underneath of the backside of the supporting metal plate 201; the distributing pipe 203 is installed on the backside of the supporting metal plate 201 by the pipe clips 204.

The longitudinal members 205 for restricting rivulets' flow meandering divide the backside of the supporting metal plate 201 into a set of parallel zones; the longitudinal members 205 entrap the rivulets when they meet the longitudinal members 205 with following flow of the rivulets along the longitudinal members 205.

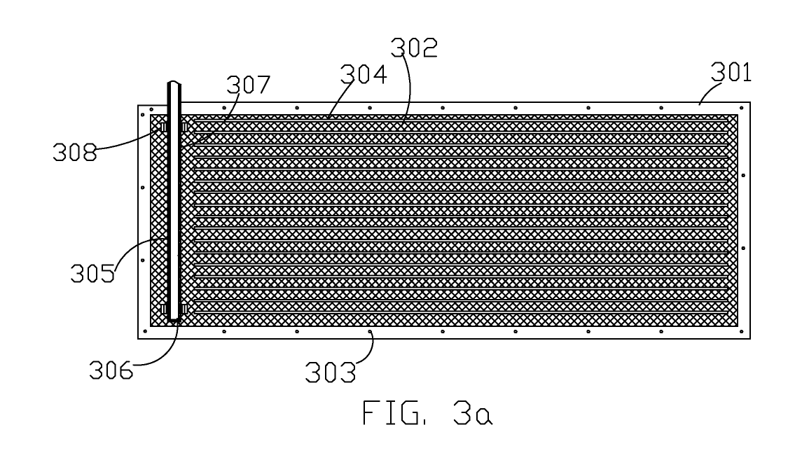

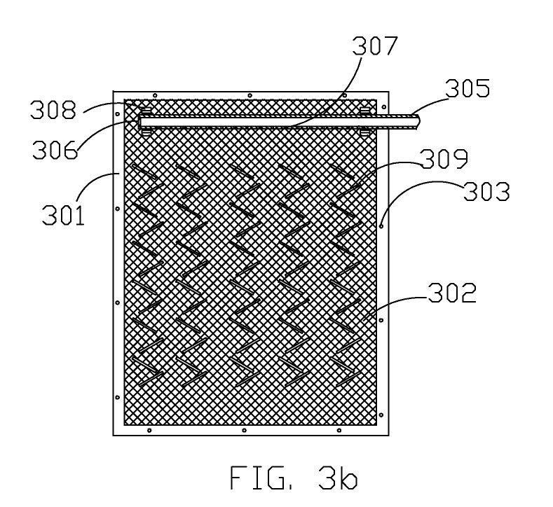

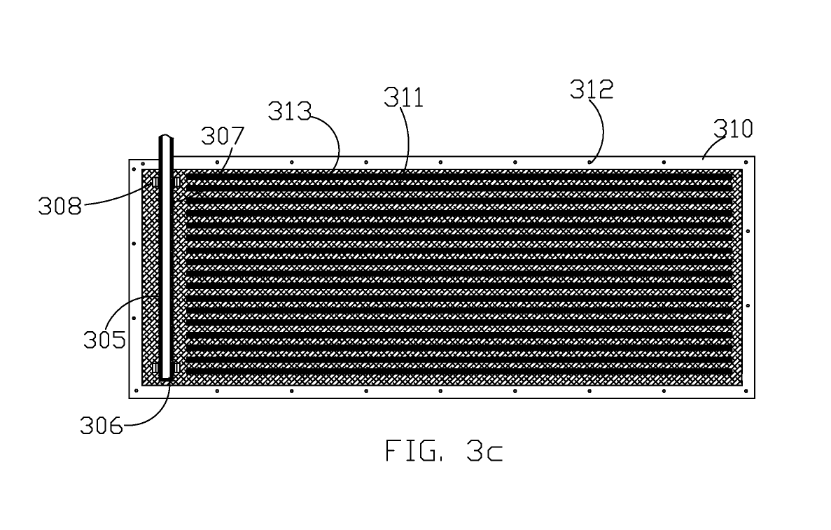

FIG. 3a demonstrates an underside view of a supporting steel plate 301 serving for installation of a photovoltaic panel on its front side.

The backside of the supporting steel plate 301 is provided with a corrosion resisting coating 302 and openings 303 serving for installation of the supporting steel plate 301.

A bank of fridge magnets strips 304 and a distributing pipe 305 are fastened on the backside of the supporting steel plate 301. The distributing pipe 305 is provided with a distal plug 306 and openings 307; this distributing pipe 305 is fastened on the backside of the supporting steel plate by pipe clips 308.

FIG. 3b demonstrates an underside view of the supporting steel, plate 301 serving for installation of a photovoltaic panel on its front side with a zigzag arrangement of fridge magnet strips 309 and the distributing pipe 305 fastened on the backside of the supporting steel plate 301 The backside of the supporting steel plate 301 is provided with a corrosion resisting coating 302 and openings 303 serving for installation of the supporting steel plate 301.

The distributing pipe 305 is provided with the distal plug 306 and openings 307; the distributing pipe 305 is fastened on the backside of the supporting steel plate 301 by the pipe clips 308.

FIG. 3c demonstrates an underside view of a supporting metal plate 310 serving for installation of a photovoltaic panel.

The backside of the supporting metal plate 310 is provided with a corrosion resisting hydrophobic coating 311 and openings 312 serving for installation of the supporting metal plate 310.

The distributing pipe 305 is fastened on the backside of the supporting metal plate 310. The distributing pipe 305 is provided with a distal plug 306 and openings 307; the distributing pipe 305 is fastened on the backside of the supporting metal plate 310 by the pipe clips 308.

The corrosion resisting hydrophobic coating 311 is provided with longitudinal hydrophilic lands 313.

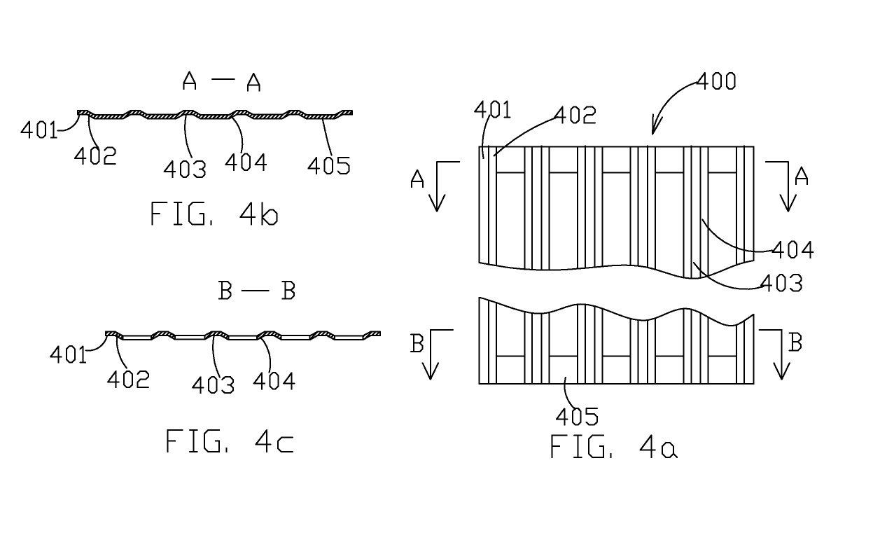

FIG. 4a, FIG. 4b and FIG. 4c are a top view and transverse cross-sections A-A and B-B of a grate-wise bank 400 of strips provided with beads. This grate-wise bank of strips is fabricated preferably from ferromagnetic steel.

It comprises: extreme strips 401 with beads 402; intervening strips 403 with their beads 404; webs 405, which serve for joining neighboring beads 402 and 404.

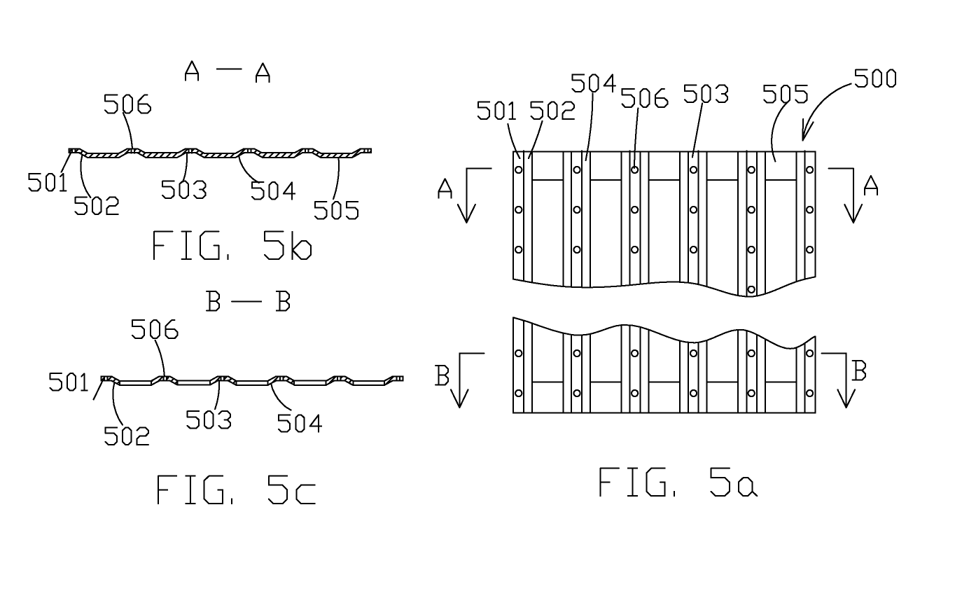

FIG. 5a, FIG. 5b and FIG. 5c are a top view and transverse cross-sections A-A and B-B of a grate-wise bank 500 of strips with beads, wherein these strips are provided with openings.

It comprises: extreme strips 501 with beads 502; intervening strips 503 with their beads 504; webs 505; openings 506, which are formed in the extreme strips 501 and the intervening strips 503.

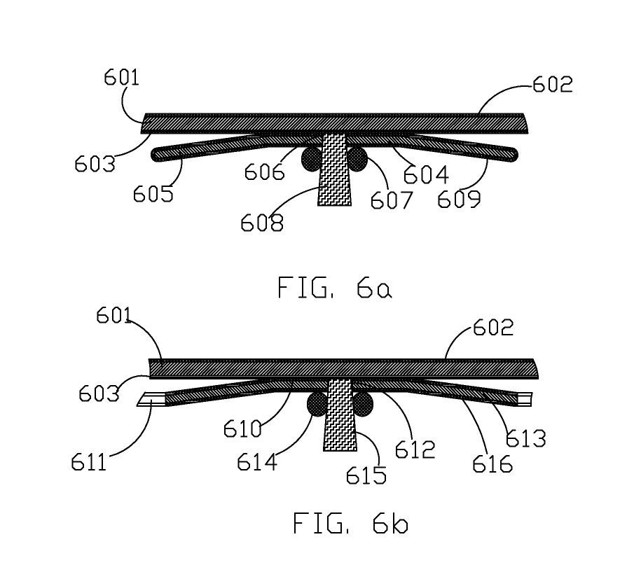

FIG. 6a and FIG. 6b are cutaway transverse views of a supporting steel plate serving for installation of a photovoltaic panel with fastening a strip (FIG. 6a) or a grate-wise bank of strips (FIG. 6b) by permanent magnets, wherein the strip or of the grate-wise bank of strips are provided with openings.

FIG. 6a shows: a supporting steel plate 601 serving for installation of a photovoltaic panel, this supporting steel plate is fabricated preferably from ferromagnetic steel; the front side of the supporting steel plate 601 is provided with a corrosion resisting coating 602 and its the backside is provided with a corrosion resisting coating 603. Strip 604 is installed on the backside of the supporting steel plate 601; this strip 604 is provided with two beads 605 and covered (including beads 605) with a corrosion resisting coating 609. Strip 604 is provided with some openings 606, which serve for installation of truncated conical permanent magnets 608, which, in turn, serve for installation of O-rings 607.

FIG. 6b comprises; the supporting steel plate 601 serving for installation of a photovoltaic panel, this supporting steel plate is fabricated preferably from ferromagnetic steel; the front side of this supporting steel plate 601 is provided with the corrosion resisting coating 602 and its backside is provided with the corrosion resisting coating 603.

Strip 610, which presents a section of a grate-wise bank of the strips, is installed on the backside of the supporting steel plate 601; this strip is provided with two beads 613 and covered (including beads 613) with a corrosion resisting coating 616. Webs 611 serve for joining beads 613 of the aforementioned bank of strips 610.

Strip 610 is provided with some openings 612, which serve for installation of truncated conical permanent magnets 615 and, in turn, these truncated conical permanent magnets 615 serve for installation of O-rings 614.

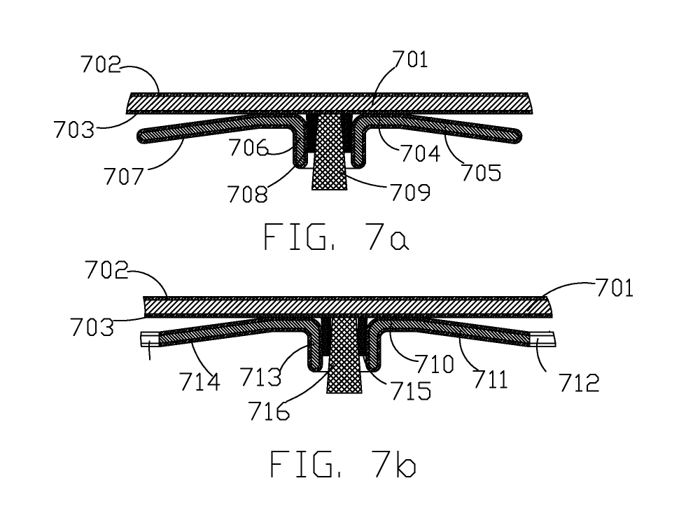

FIG. 7a and FIG. 7b are cutaway transverse views of a supporting steel plate with installation of a strip (FIG. 7a) or a grate-wise bank of strips (FIG. 7b) by truncated conical permanent magnets, wherein the strip (or the grate-wise bank of strips) is provided with flanged openings.

FIG. 7a shows: the supporting steel plate 701 fabricated preferably from ferromagnetic steel and serving for installation of a photovoltaic panel; the front side of the supporting steel plate 701 is provided with a corrosion resisting coating 702, and its backside is provided with a corrosion resisting coating 703. Strip 704 is installed on the backside of the supporting steel plate 701; this strip is provided with two beads 705 and covered (including beads 705) with a corrosion resisting coating 707. Strip 704 is provided with some openings with outward flanges 706, which serve for installation of O-rings 708 and truncated conical permanent magnets 709.

FIG. 7b shows: the supporting steel plate 701 fabricated preferably from ferromagnetic steel and serving for installation of a photovoltaic panel; the front side of the supporting steel plate 701 is provided with the corrosion resisting coating 702 and its the backside is provided with the corrosion resisting coating 703. Strip 710, which belongs to the grate-wise bank of strips, is installed on the backside of the supporting steel plate 701; this strip 710 is provided with two beads 711 and covered (including beads 711) with a corrosion resisting coating 714. Webs 712 serve for joining beads 711 of the aforementioned bank of strips 710.

Strip 710 is provided with some openings with outward flanges 713, which serve for installation of O-rings 715 and truncated conical permanent magnet 716.

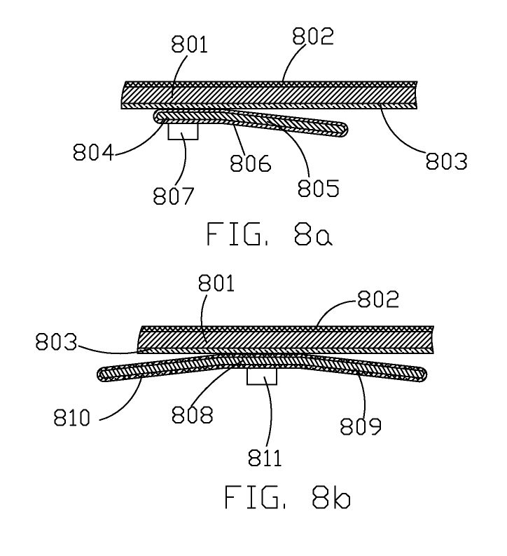

FIG. 8a and FIG. 8b are cutaway transverse views of a supporting steel plate 801 fabricated preferably from ferromagnetic steel and serving for installation of a photovoltaic panel; the supporting steel plate 801 serves for fastening a strip with one bead (FIG. 8a) or a strip with two beads (FIG. 8b) by external permanent magnets.

FIG. 8a shows: the supporting steel plate 801; the front side of the supporting steel plate 801 is provided with a corrosion resisting coating 802 and its the backside is provided with a corrosion resisting coating 803. Strip 804, which is fabricated from ferromagnetic steel, is installed on the backside of the supporting steel plate 801; the strip 804 is provided with one bead 805 and covered (including bead 805) with a corrosion resisting coating 806. Strip 804 is secured on the supporting steel plate 801 by an external permanent magnet 807.

FIG. 8b shows the supporting steel plate 801; the front side of the supporting steel plate 801 is provided with the corrosion resisting coating 802 and its the backside is provided with the corrosion resisting coating 803. Strip 808, which is fabricated from ferromagnetic steel, is installed on the backside of the supporting steel plate 801; the strip 808 is provided with two beads 809 and covered (including beads 809) with a corrosion resisting coating 810. Strip 808 is secured on the supporting steel plate 801 by an external permanent magnet 811.

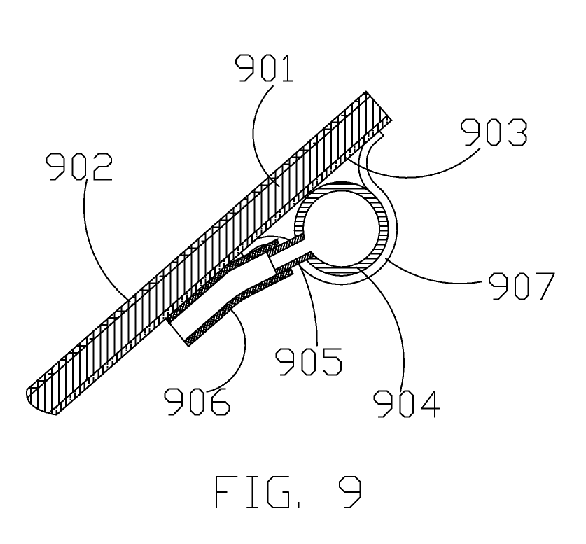

FIG. 9 is a cutaway transverse view of the upper section of a supporting metal plate 901 serving for installation of a photovoltaic panel with a distributing pipe 904, which is installed on the upper section of the backside of the supporting metal plate 901.

The drawing depicts: the supporting metal plate 901; the front side of the supporting metal plate 901 is provided with a corrosion resisting coating 902; the backside of the supporting metal plate 901 is provided with a corrosion resisting coating 903; the distributing pipe 904 is provided with nozzles 905, which are terminated with flexible sleeves 906; pipe clips 907 are installed on the backside of the supporting metal plate 901 and serve for securing the distributing pipe 904.

What is claimed is:

1. A supporting structure for active cooling a photovoltaic solar panel, said supporting structure consists of:
a supporting structural frame, which comprises in turn a top rectangular frame and a bottom rectangular frame joined by some connectors; said top rectangular frame serves for installation of a supporting metal plate, which serves for mounting said photovoltaic solar panel with its back sheet on said supporting metal plate by adhesive; said supporting structural frame is positioned in its operating state in such a way, that said top rectangular frame is tilted with respect to the horizontal plane;
a receiving chute, which is joined with the lower section of the backside of said supporting metal plate; said receiving chute is provided with an outlet connection serving for removal of cooling liquid medium;
a distributing pipe; the proximal section of said distributing pipe is placed outside said supporting metal plate, and its middle and distal sections are installed on the backside of said supporting metal plate; the middle and distal sections of said distributing pipe are provided with openings, which supply evenly water or another cooling liquid medium on the upper section of the backside of said supporting metal plate; the upper section of the backside of said supporting metal plate is provided with some pipe clips serving for fastening said distributing pipe;
longitudinal members for restricting rivulets' flow meandering; said longitudinal member divide the backside of said supporting metal plate into a set of parallel zones; said longitudinal members entrap the rivulets when they meet said longitudinal members with following transformation of the shapes of said rivulets and their flowing in their transformed shapes along said longitudinal members.

2. The supporting structure for active cooling a photovoltaic solar panel as claimed in claim 1, wherein the supporting structural frame serves as a skeleton for construction of a housing instead of the receiving chute; said housing comprises a bottom wall, lateral walls, a proximal face wall and a distal face wall; said lateral walls are provided with one opening in one of their upper sections for insertion of the distributing pipe, with a venting hole and with an outlet connection in one of their lower sections for drainage of the cooling liquid medium.

3. The supporting structure for active cooling a photovoltaic solar panel as claimed in claim 1, wherein the supporting metal plate is a supporting steel plate from ferromagnetic steel; said supporting steel plate is provided with corrosion resisting coatings from its both sides and the longitudinal members for restricting rivulets' flow meandering; there are strips fabricated from fridge magnets or polymer bond magnets, which are arranged on the backside of said supporting steel plate with formation of longitudinal zones separated by said strips.

4. The supporting structure for active cooling a photovoltaic solar panel as claimed in claim 3, wherein short fridge magnet strips are arranged on the backside of the supporting steel plate as vertical rows of the cascade-wise fridge magnet strips and each fridge magnet strip in one row of the vertical cascade-wise system has a certain angle with the longitudinal direction of said supporting steel plate.

5. The supporting structure for active cooling a photovoltaic solar panel as claimed in claim 1, wherein a bank of longitudinal strips from any corrosion resisting material is joined with the backside of the supporting metal plate by seam or spot welding, soldering or gluing with thermo-stable glue.

6. The supporting structure for active cooling a photovoltaic solar panel as claimed in claim 1, wherein the supporting metal plate is a supporting steel plate from ferromagnetic steel; there are parallel steel strips with analogical ferromagnetic properties, which are covered on their both sides and their edges with corrosive resisting coating, and they are placed apart longitudinally with a certain mutual interval on the backside of said supporting steel plate; each said steel strip is fastened on the backside of the supporting eel plate by some permanent magnets.

7. The supporting structure for active cooling a photovoltaic solar panel as claimed in claim 6, wherein the steel strip is provided with at least one longitudinal bead, which forms a wedge-wise gap with the adjacent surface of the backside of the supporting steel plate.

8. The supporting structure for active cooling a photovoltaic solar panel as claimed in claim 7, wherein the steel strips are constructed as a grate with a frame comprising two lateral steel strips with one bead each one; intermediate steel strips with two bead each one; and upper and lower webs, which join said beads of said neighboring steel strips.

9. The supporting structure for active cooling a photovoltaic solar panel as claimed in claim 7, wherein the strips are fabricated from any corrosion-resisting material and each said strip is provided with some openings and O-rings or back-up rings, which are placed concentrically with said openings; the diameter of each said opening lies in the interval between the inner diameter of said O-ring and its outer diameter; a truncated conical permanent magnet, which has its top diameter smaller than the inner diameter of said O-ring and its base diameter is larger than the inner diameter of said O-ring, is inserted with its truncated section into said opening until its immediate contact with the backside of the supporting steel plate.

10. The supporting structure for active cooling a photovoltaic solar panel as claimed in claim 9, wherein the permanent magnets have a cylindrical form and the diameter of said permanent cylindrical magnet is larger than the inner diameter of the O-ring.

11. The supporting structure for active cooling a photovoltaic solar panel as claimed in claim 7, wherein the strips are fabricated from any corrosion-resisting material and each said strip is provided with one or two longitudinal beads and some openings, wherein each said opening is provided with a vertical flanging; an O-ring or a back-up ring is inserted into each opening; a truncated conical permanent magnet is inserted into said opening until its immediate contact with the backside of the supporting steel with attendant deformation of said O-ring or said back-up ring.

12. The supporting structure for active cooling a photovoltaic solar panel as claimed in claim 1, wherein the backside of the supporting metal plate is covered with a thermo-stable hydrophobic coating; parallel longitudinal lands of the surface of said thermo-stable hydrophobic coating are treated by known methods such as plasma treating or chemical oxidation providing hydrophilic properties to said parallel longitudinal lands.

13. The supporting structure for active cooling a photovoltaic solar panel as claimed in claim 1, wherein the distributing pipe is provided with nozzles, which are terminated with flexible sleeves.

14. The supporting structure for active cooling a photovoltaic solar panel as claimed in claim 1, wherein said supporting structure is applied at nighttime for cooling a liquid medium.

15. The supporting structure for active cooling a photovoltaic solar panel as claimed in claim 14, wherein said liquid medium is water.
